(19) United States
(12) Patent Application Publication
(10) Pub. No.: US 2017/0356083 A1
(43) Pub. Date: Dec. 14, 2017

(54) Lanthanide, Yttrium And Scandium Precursors For ALD, CVD And Thin Film Doping And Methods Of Use

(71) Applicant: Applied Materials, Inc., Santa Clara, CA (US)

(72) Inventors: Jeffrey W. Anthis, San Jose, CA (US); Benjamin Schmiege, Santa Clara, CA (US)

(21) Appl. No.: 15/621,023

(22) Filed: Jun. 13, 2017

Related U.S. Application Data
(60) Provisional application No. 62/359,381, filed on Jul. 7, 2016.
(60) Provisional application No. 62/349,628, filed on Jun. 13, 2016.

(51) Int. Cl. C23C 16/18; C07F 19/00; C23C 16/30; C23C 16/455

(52) U.S. Cl. CPC C23C 16/18; C23C 16/45536; C07F 19/00; C23C 16/45525; C23C 16/30

(57) ABSTRACT

Methods for depositing a film comprising exposing a substrate surface to a metal precursor and a co-reactant to form a metal containing film are described. The metal precursor comprises a metal atom and an allyl ligand, the metal atom comprises one or more lanthanide.

### CROSS-REFERENCE TO RELATED APPLICATIONS

This application claims priority to U.S. Provisional Application No. 62/359,381, filed Jul. 7, 2016, and U.S. Provisional Application No. 62/349,628, filed Jun. 13, 2016, the entire disclosures of which are hereby incorporated by reference herein.

### TECHNICAL FIELD

The present disclosure relates generally to methods of depositing films and doping films. In particular, the disclosure relates to methods of depositing or doping films using lanthanide, yttrium and scandium precursors.

### BACKGROUND

The push to engineer smaller and smaller microelectronic devices has opened up an increasing portion of the periodic table. While there is a large amount of research on Ln, Y and Sc inorganic and organometallic compounds, developing new compounds and exploring reactivity, there has been little progress in improving properties for vapor deposition methods. Ln, Y and Sc metal compounds typically suffer from low volatility and a challenging balance to maintain both chemical stability and high enough reactivity with typical deposition co-reactants.

There is a need in the art for methods depositing and doping films using lanthanide, yttrium and scandium precursors.

### SUMMARY

One or more embodiments of the disclosure are directed to processing methods comprising exposing a substrate surface to a metal precursor and a co-reactant to form a metal containing film. The metal precursor comprises a metal atom and an allyl ligand. The metal atom comprises one or more lanthanide.

Additional embodiments of the disclosure are directed to processing methods comprising exposing a substrate surface to a metal precursor and a co-reactant to form a metal containing film. The metal precursor comprises a metal atom and an allyl ligand. The metal atom comprises one or more of La, Ce, Pr, Nd, Pm, Sm, Eu, Gd, Tb, Dy, Ho, Er, Tm, Yb, Lu, Y or Sc.

Further embodiments of the disclosure are directed to processing methods comprising exposing a substrate surface to a metal precursor and a co-reactant to form a metal containing film. The metal precursor comprises a metal atom comprising one or more of La, Ce, Pr, Nd, Pm, Sm, Eu, Gd, Tb, Dy, Ho, Er, Tm, Yb, Lu, Y or Sc. The metal precursor further comprises at least one allyl ligand and at least one ligand selected from the group consisting of cyclopentadiene, substituted cyclopenadiene, amidinate and substituted amidinate.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure advantageously provide methods of depositing a lanthanide, yttrium or scandium film. Some embodiments advantageously provide chemical vapor deposition (CVD) or atomic layer deposition (ALD) methods to deposit film using precursors with allyl ligands. Some embodiments advantageously provide methods of doping film using lanthanide, yttrium or scandium based films.

One or more embodiments of the disclosure are directed to the use of lanthanide, yttrium and scandium compounds containing allyl ligands for ALD, CVD and semiconductor doping applications. One or more embodiments are directed to processing methods comprising exposing a substrate surface to a metal precursor and a co-reactant to form a metal containing film. The metal precursor comprises a metal atom and an allyl ligand. The metal atom comprises one or more lanthanide metal.

The allyl ligand is a monoanionic ligand having a three carbon backbone. In organometallic compounds, the negative charge is typically delocalized over the three carbon backbone, as shown in Scheme I. Without being bound by any particular theory of operation, it is believed that each of the carbon atoms may be considered bound to the metal.

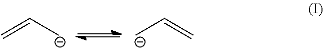

Embodiments of the disclosure are directed to lanthanide, yttrium and scandium compounds containing one, two or three allyl ligands. As used in this specification and the appended claims, the term “lanthanide” means any element from the lanthanum series: lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu); and the term “lanthanide” also includes yttrium (Y) and scandium (Sc). The allyl ligands may be substituted at any of the carbon positions. Lanthanide compounds exist in the +3 oxidation state; however, those skilled in the art will understand that other oxidation states exist for these elements.

In some embodiments, compounds contain one or two allyl ligands and one or two cyclopentadienyl ligands. An exemplary lanthanide precursor is shown as structure (II).

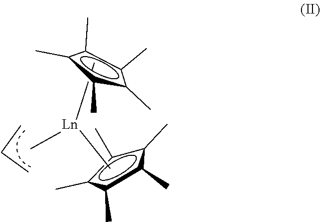

Those skilled in the art will understand that the atom labeled Ln can be any of the lanthanides. Suitable metal precursors include, but are not limited to, Cp₂Ln(allyl), CpLn(allyl)₂, (allyl)₃Ln, where Cp is a substituted or un-substituted cyclopentadienyl ligand, allyl is a substituted or un-substituted ally ligand and Ln is any of La, Ce, Pr, Nd, Pm, Sm, Eu, Gd, Tb, Dy, Ho, Er, Tm, Yb, Lu, Y or Sc.

In some embodiments, the metal precursor comprises one, two, three or four allyl ligands. The allyl ligand can be un-substituted, having a formula of C₃H₅. In some embodiments, the allyl ligand is substituted at one or more of the carbon atoms. Suitable substituted ally ligands include ligands with C₁₋₆ branched or unbranched alkyl groups (i.e., alkyl groups with one, two, three, four, five or six carbon atoms), C₁₋₆ branched or unbranched alkenyl groups, C₁₋₆ branched or unbranched alkynyl groups, cycloalkyl groups and trimethylsilyl (TMS) groups. In some embodiments, the allyl ligand is substituted at one carbon atom. In some embodiments, the allyl ligand is substituted at two carbon atoms.

In some embodiments, the metal precursor comprises one allyl ligand and two ligands independently selected from cyclopentadiene, substituted cyclopenadiene, amidinate and substituted amidinate. In one or more embodiments, the two ligands are the same ligand (e.g., both Cp rings). In some embodiments, the two ligands are different ligands so that there are three or four different ligands associated with the metal atom.

In some embodiments, the metal precursor comprises a cyclopentadienyl ligand. The cyclopentadienyl ligand of one or more embodiments has the general formula C₅R₅, where each R is independently H, C₁₋₆ alkyl or SiMe₃. In some embodiments, the cyclopentadienyl ligand comprises C₅Me₅. In one or more embodiments, the cyclopentadienyl ligand comprises C₅Me₄H. In some embodiments, the cyclopentadienyl ligand comprises C₅Me₄SiMe₃.

For compounds containing one or two allyl ligands, the remaining ligands may be one or two amidinate ligands. An exemplary metal precursor with amidinate ligands is shown in Structure (III).

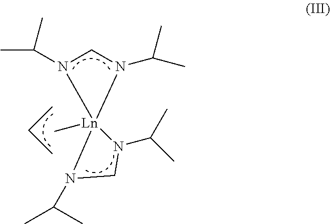

In some embodiments, the metal precursor comprises an amidinate ligand having the general formula RNCR′NR, where each R and R′ is independently H, a C₁₋₆ alkyl or SiMe₃. In some embodiments, the metal precursor comprises (RNCR′NR)₂Ln(allyl) or (RNCR′NR)Ln(allyl)₂.

The metal precursor can be reacted with oxidizing co-reactants such as H₂O, O₂, O₃, oxygen plasma, H₂O₂, NO or NO₂ to form a metal oxide film. As used in this regard, a “metal oxide” film comprises metal atom and oxygen atoms. A metal oxide film can be non-stoichiometric. A film “consisting essentially of” metal oxide has greater than or equal to about 95, 96, 97, 98 or 99 atomic percent metal and oxygen atoms.

In some embodiments, the co-reactant comprises one or more of NO, NO₂, NH₃, N₂H₂ or plasma thereof and the metal containing film comprises a metal nitride. As used in this regard, a “metal nitride” film comprises metal atoms and nitrogen atoms. A metal nitride film can be non-stoichiometric. A film “consisting essentially of” metal nitride has greater than or equal to about 95, 96, 97, 98 or 99 atomic percent metal and nitrogen atoms.

In some embodiments, the co-reactant comprises an organic species and the film comprises a metal carbide. Suitable organic species include, but are not limited to, propylene and acetylene. As used in this regard, a “metal carbide” film comprises metal atoms and carbon atoms. A metal carbide film can be non-stoichiometric. A film “consisting essentially of” metal carbide has greater than or equal to about 95, 96, 97, 98 or 99 atomic percent metal and carbon atoms.

In some embodiments, the metal containing film deposited comprises one or more of a metal carbide (MC), metal oxide (MO), metal nitride (MN), metal oxycarbide (MCO), metal oxynitride (MNO), metal carbonitride (MCO) or metal oxycarbonitride film (MCON). The metal carbide, metal oxide, metal nitride, metal oxycarbide, metal oxynitride, metal carbonitride and metal oxycarbonitride films are made up of the components named in any suitable amount, either stoichiometrically or non-stoichiometrically. A film that consists essentially of the named component has greater than or equal to about 95, 96, 97, 98 or 99 percent of the named components on an atomic basis.

In some embodiments, the film formed is a doped metal oxide film in which dopant elements are added (e.g., B, P, As). Doping of the film can be done at the same time as film formation by, for example, addition of a dopant precursor, or separately by, for example, ion implantation.

The metal film can be deposited by a CVD process in which the metal precursor and the co-reactant are mixed prior to or at the time of exposure to the substrate surface. Mixing the metal precursor and the co-reactant may allow gas phase reactions which can deposit on the substrate surface.

In some embodiments, the metal film is deposited by an ALD process in which the metal-precursor and co-reactant are exposed to the substrate surface separately and sequentially so that the metal precursor and co-reactant do not mix. For example, in a time-domain ALD process, the entire substrate surface is exposed to the metal precursor and then the co-reactant with a purge step between to prevent gas phase mixing. Only one of the metal precursor and the co-reactant are flowed into the processing chamber at a time in the time-domain ALD process.

In a spatial ALD process, the metal precursor and the co-reactant are flowed into different portions of the processing chamber and separated by, for example, a gas curtain or physical barrier to prevent gas phase mixing and reaction. In spatial ALD, a portion of the substrate surface may be exposed to the metal precursor and a separate portion of the substrate surface may be exposed to the co-reactant at the same time while separating of the gases is maintained.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A processing method comprising exposing a substrate surface to a metal precursor and a co-reactant to form a metal containing film, the metal precursor comprising a metal atom and an allyl ligand, the metal atom comprising one or more lanthanide.

2. The processing method of claim 1, wherein the lanthanide is one or more of La, Ce, Pr, Nd, Pm, Sm, Eu, Gd, Tb, Dy, Ho, Er, Tm, Yb, Lu, Y or Sc.

3. The processing method of claim 1, wherein there are three allyl ligands.

4. The processing method of claim 1, wherein there is one allyl ligand and two different ligands independently selected from cyclopentadiene, substituted cyclopenadiene, amidinate, substituted amidinate.

5. The processing method of claim 1, wherein the allyl ligand is a substituted allyl ligand.

6. The processing method of claim 5, wherein the substituted allyl ligand has a C₁₋₆ alkyl, C₁₋₆ alkenyl, C₁₋₆ alkynyl, branched alkyl or cycloalkyl group.

7. The processing method of claim 1, wherein the metal precursor further comprises a cyclopentadienyl ligand.

8. The processing method of claim 7, wherein the cyclopentadienyl ligand has the general formula C₅R₅, where each R is independently H, C₁₋₆ alkyl or SiMe₃.

9. The processing method of claim 8, wherein the cyclopentadienyl ligand comprises C₅Me₅.

10. The processing method of claim 8, wherein the cyclopentadienyl ligand comprises C₅Me₄H.

11. The processing method of claim 8, wherein the cyclopentadienyl ligand comprises C₅Me₄SiMe₃.

12. The processing method of claim 1, wherein the metal precursor comprises an amidinate ligand having the general formula RNCR′NR, where each R and R′ is independently H, a C₁₋₆ alkyl or SiMe₃.

13. The processing method of claim 1, wherein the co-reactant comprises one or more of H₂O, O₂, O₃, O plasma, H₂O₂, NO or NO₂ and the metal containing film comprises a metal oxide.

14. The processing methods of claim 1, wherein the co-reactant comprises one or more of NO, NO₂, NH₃, N₂H₂ or plasma thereof and the metal containing film comprises a metal nitride.

15. The processing method of claim 1, wherein the co-reactant comprises an organic species and the film comprises a metal carbide.

16. The processing method of claim 1, wherein the metal containing film comprises one or more of a metal carbide, metal oxide, metal nitride, metal oxycarbide, metal oxynitride, metal carbonitride or metal oxycarbonitride film.

17. The processing method of claim 1, wherein the metal precursor and the co-reactant are exposed to the substrate surface in a mixture.

18. The processing method of claim 1, wherein the metal precursor and the co-reactant are exposed to the substrate surface sequentially so that the metal precursor and co-reactant do not mix.

19. A processing method comprising exposing a substrate surface to a metal precursor and a co-reactant to form a metal containing film, the metal precursor comprising a metal atom and an allyl ligand, the metal atom comprising one or more of La, Ce, Pr, Nd, Pm, Sm, Eu, Gd, Tb, Dy, Ho, Er, Tm, Yb, Lu, Y or Sc.

20. A processing method comprising exposing a substrate surface to a metal precursor and a co-reactant to form a metal containing film, the metal precursor comprising a metal atom comprising one or more of La, Ce, Pr, Nd, Pm, Sm, Eu, Gd, Tb, Dy, Ho, Er, Tm, Yb, Lu, Y or Sc, the metal precursor further comprising at least one allyl ligand and at least one ligand selected from the group consisting of cyclopentadiene, substituted cyclopenadiene, amidinate and substituted amidinate.
